(19) United States
(12) Patent Application Publication
(10) Pub. No.: US 2024/0319594 A1
(43) Pub. Date: Sep. 26, 2024

(54) RESIST COMPOSITION AND METHOD OF FORMING PATTERN USING THE SAME

(71) Applicant: Samsung Electronics Co., Ltd., Suwon-si (KR)

(72) Inventors: Chanjae AHN, Suwon-si (KR); Cheol KANG, Suwon-si (KR); Minsang KIM, Suwon-si (KR); Beomseok KIM, Suwon-si (KR); Changki KIM, Suwon-si (KR); Hana KIM, Suwon-si (KR); Hyeran KIM, Suwon-si (KR); Changheon LEE, Suwon-si (KR); Sungwon CHOI, Suwon-si (KR); Hyunseok CHOI, Hwaseong-si (KR)

(73) Assignee: Samsung Electronics Co., Ltd., Suwon-si (KR)

(21) Appl. No.: 18/493,192

(22) Filed: Oct. 24, 2023

(30) Foreign Application Priority Data
Mar. 24, 2023 (KR) 10-2023-0039145
May 11, 2023 (KR) 10-2023-0061347

(51) Int. Cl. G03F 7/039; C08F 212/14; C08F 220/18; G03F 7/038

(52) U.S. Cl. CPC G03F 7/039; C08F 212/24; C08F 212/28; C08F 220/1806; C08F 220/1807; G03F 7/038

(57) ABSTRACT

Provided are a resist composition and a pattern forming method using the same. The resist composition includes a polymer including a first repeating unit repeating unit Formula 1, a photoacid generator, and an organic solvent.

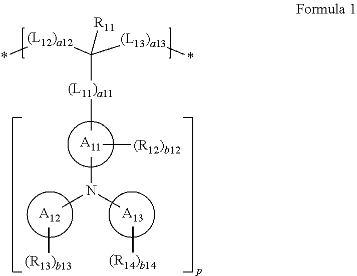

In Formula 1, L₁₁ to L₁₃, a₁₁ to a₁₃, A₁₁ to A₁₃, R₁₁ to R₁₄, b₁₂ to b₁₄, and p are the same as described in the detailed description.

### CROSS-REFERENCES TO RELATED APPLICATION

This application is based on and claims priority under 35 U.S.C. § 119 to Korean Patent Application Nos. 10-2023-0039145, filed on Mar. 24, 2023, and 10-2023-0061347, May 11, 2023, in the Korean Intellectual Property Office, the disclosures of which are incorporated by reference herein in their entirety.

### BACKGROUND

### 1. Field

The disclosure relates to a resist composition and a pattern forming method using the same.

### 2. Description of the Related Art

During manufacturing of semiconductors, resists, of which physical properties change in response to light, are being used to form fine patterns. Among the resistors, chemically amplified resists have been widely used. A chemically amplified resist enables patterning by allowing acids, formed by the reaction of light with photoacid generators, to react back with a base resin, changing the solubility of the base resin in a developing solution.

In particular, when using high-energy rays with relatively very high energy, such as EUV, the number of photons is significantly smaller than when irradiating light of the same energy. Accordingly, there may be a need for resist compositions that can be effective when used in small amounts, and that can provide improved sensitivity and/or resolution.

### SUMMARY

Provided are a resist composition and a pattern forming method using the same, the resist composition being capable of providing improved sensitivity and/or resolution.

Additional aspects will be set forth in part in the description which follows and, in part, will be apparent from the description, or may be learned by practice of the presented embodiments of the disclosure.

According to an embodiment of the disclosure, a resist composition includes a polymer including a first repeating unit represented by Formula 1, a photoacid generator, and an organic solvent:

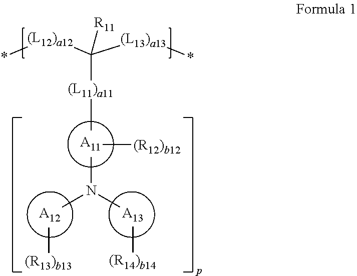

In Formula 1,
L₁₁ to L₁₃ may each independently be a single bond, O, S, C(═O), C(═O)O, OC(═O), C(═O)NH, NHC(═O), or a linear, branched, or cyclic C₁-C₃₀ divalent hydrocarbon group which may optionally contain a hetero atom,
a11 to a13 may each independently be an integer from 1 to 4;
A₁₁ to A₁₃ may each independently be a C₆-C₃₀ aryl group,
R₁₁ to R₁₄ may each independently be hydrogen, deuterium, halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group which may optionally contain a hetero atom,
an adjacent two of R₁₂, R₁₃ and R₁₄ may be optionally bonded to each other to form a condensed ring,
b12 to b14 may each independently be selected from an integer from 1 to 10,
p may be an integer from 1 to 5, and
* may be a binding site with an adjacent atom.

According to an embodiment of the disclosure, a pattern forming method includes forming a resist film by applying the resist composition, exposing at least a portion of the resist film with high energy rays to provide an exposed resist film; and developing the exposed resist film using a developing solution.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a pattern forming method according to an embodiment;

FIGS. 2A to 2C are side cross-sectional views illustrating the pattern forming method according to an embodiment;

FIGS. 3A to 3D are graphs of normalized remaining film thickness according to the amount of exposed light evaluated in Evaluation Example 3;

FIGS. 4A to 4E are side cross-sectional views illustrating a method of forming a patterned structure according to an embodiment; and

FIGS. 5A to 5E are side cross-sectional views illustrating a method of forming a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Since the disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cₓ-C_{y}” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound containing carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e.g., a phenyl group, a 1-naphthyl group, and a 2-naphthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or a combination thereof. In addition, in these groups, some hydrogen atoms may be substituted by a moiety including a heteroatom such as oxygen, sulfur, nitrogen, or halogen, or some carbon atoms may be substituted by a moiety including a heteroatom such as oxygen, sulfur, or nitrogen so that the groups may include a hydroxy group, a cyano group, a carbonyl group, a carboxyl group, an ether bond, an ester bond, a sulfonate ester bond, carbonate, a lactone ring, a sultone ring, a carboxylic anhydride moiety, or a haloalkyl moiety.

The term “divalent hydrocarbon group” as used herein is a divalent residue and means that any one hydrogen atom of the monovalent hydrocarbon group is replaced with a bonding site with an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. The term “alkylene group” as used herein refers to a linear or branched saturated aliphatic hydrocarbon divalent group, and specific examples thereof include a methylene group, an ethylene group, a propylene group, a butylene group, an isobutylene group, and the like.

The term “halogenated alkyl group” as used herein refers to a group in which one or more hydrogen atoms of an alkyl group are substituted with halogen, and specific examples thereof include CF₃ and the like.

The term “alkoxy group” as used herein refers to a monovalent group having a formula of —OA₁₀₁, wherein A₁₀₁ is an alkyl group. Specific examples thereof include a methoxy group, an ethoxy group, an isopropyloxy group, and the like.

The term “alkylthio group” as used herein refers to a monovalent group having a formula of —SA₁₀₁, wherein A₁₀₁ is an alkyl group.

The term “halogenated alkoxy group” as used herein refers to a group in which one or more hydrogen atoms of an alkoxy group are substituted with halogen, and specific examples thereof include —OCF₃ and the like.

The term “halogenated alkylthio group” as used herein refers to a group in which one or more hydrogen atoms of an alkylthio group are substituted with halogen, and specific examples thereof include —SCF₃ and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group having a formula of —OA₁₀₂, wherein A₁₀₂ is a cycloalkyl group. Specific examples thereof include a cyclopropoxy group, a cyclobutoxy group, and the like.

The term “cycloalkylthio group” as used herein refers to a monovalent group having a formula of —SA₁₀₂, wherein A₁₀₂ is a cycloalkyl group.

The term “heterocycloalkyl group” as used herein may be a group in which some carbon atoms of the cycloalkyl group are replaced by a moiety including a heteroatom, for example, oxygen, sulfur, or nitrogen. The heterocycloalkyl group may include an ether bond, an ester bond, a sulfonate ester bond, carbonate, a lactone ring, a sultone ring, or a carboxylic anhydride moiety. The term “heterocycloalkylene group” as used herein refers to a group in which some carbon atoms of the cycloalkylene group are replaced by a moiety including a heteroatom, for example, oxygen, sulfur, or nitrogen.

The term “heterocycloalkoxy group” as used herein refers to a monovalent group having a formula of —OA₁₀₃, wherein A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “alkenyloxy group” as used herein refers to a monovalent group having a formula of —OA₁₀₄, wherein A₁₀₄ is an alkenyl group.

The term “cycloalkenyl group” as used herein refers to a monovalent unsaturated hydrocarbon cyclic group including one or more carbon-carbon double bonds. The term “cycloalkenylene group” as used herein refers to a divalent unsaturated hydrocarbon cyclic group including one or more carbon-carbon double bonds.

The term “cycloalkenyloxy group” as used herein refers to a monovalent group having a formula of —OA₁₀₅, wherein A₁₀₅ is a cycloalkenyl group.

The term “heterocycloalkenyl group” as used herein refers to a group in which some carbon atoms of the cycloalkenylene group are replaced by a moiety including a heteroatom, for example, oxygen, sulfur, or nitrogen. The term “heterocycloalkenylene group” as used herein refers to a group in which some carbon atoms of the cycloalkenylene group are replaced by a moiety including a heteroatom, for example, oxygen, sulfur, or nitrogen.

The term “heterocycloalkenyloxy group” as used herein refers to a monovalent group having a formula of —OA₁₀₆, wherein A₁₀₆ is a heterocycloalkenyl group.

The term “alkynyl group” as used herein refers to a linear or branched unsaturated aliphatic hydrocarbon monovalent group including one or more carbon-carbon triple bonds.

The term “alkynyloxy group” as used herein refers to a monovalent group having a formula of —OA₁₀₇, wherein A₁₀₇ is an alkynyl group.

The term “aryl group” as used herein refers to a monovalent group having a carbocyclic aromatic system, and specific examples thereof include a phenyl group, a naphthyl group, an anthracenyl group, a phenanthrenyl group, a pyrenyl group, a chrysenyl group, and the like.

The term “aryloxy group” as used herein refers to a monovalent group having a formula of —OA₁₀₈, wherein A₁₀₈ is an aryl group.

The term “heteroaryl group” as used herein refers to a monovalent group having a heterocyclic aromatic system, and specific examples thereof include a pyridinyl group, a pyrimidinyl group, a pyrazinyl group, and the like. The term “heteroarylene group” as used herein refers to a divalent group having a heterocyclic aromatic system.

The term “heteroaryloxy group” as used herein refers to a monovalent group having a formula of —OA₁₀₉, wherein A₁₀₉ is a heteroaryl group.

The term “substituent” as used herein includes: deuterium, halogen, a hydroxyl group, a cyano group, a nitro group, a carbonyl group, a carboxylic acid group, an amino group, an ether moiety, an ester moiety, a sulfonate ester moiety, a carbonate moiety, amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;

a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and a combination thereof; and a combination thereof.

Hereinafter, embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Polymer]

Polymers according to example embodiments include a first repeating unit represented by Formula 1:

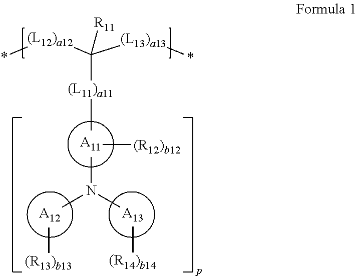

wherein, in Formula 1,

L₁₁ to L₁₃ may each independently be a single bond; O; S; C(═O); C(═O)O; OC(═O); C(═O)NH; NHC(═O); or a linear, branched, or cyclic C₁-C₃₀ divalent hydrocarbon group which may optionally contain a hetero atom,
a11 to a13 may each independently be an integer from 1 to 4;
A₁₁ to A₁₃ may each independently be a C₆-C₃₀ aryl group,
R₁₁ to R₁₄ may each independently be: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which may optionally contain a hetero atom,
an adjacent two of R₁₂, R₁₃ and R₁₄ may be optionally bonded to each other to form a condensed ring,
b12 to b14 may each independently be selected from an integer from 1 to 10,
p may be an integer from 1 to 5, and
* may be a binding site with an adjacent atom.

In some embodiments, L₁₁ to L₁₃ in Formula 1 may each independently be: a single bond; O; S; C(═O); C(═O)O; OC(═O); C(═O)NH; NHC(═O); a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

In some embodiments, L₁₁ to L₁₃ in Formula 1 may each independently be: a single bond; O; C(═O); C(═O)O; OC(═O); and a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylrene group, a C₆-C₂₀ arylene group, and a C₁-C₂₀ heteroarylene group, each unsubstituted or substituted with deuterium, halogen, a cyano group, a hydroxyl group, an amino group, a carboxylic acid group, a thiol group, an ester moiety, a sulfonic ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

In some embodiments, L₁₁ to L₁₃ in Formula 1 may each independently be: a single bond; O; O; C(═O); C(═O)O; OC(═O); and a C₁-C₂₀ alkylene group, a C₃-C₂₀ cycloalkylene group, a C₃-C₂₀ heterocycloalkylene group, a phenylene group, and a naphthylene group, each unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or a combination thereof.

In Formula 1, a11 to a13 may denote the number of repetitions of L₁₁ to L₁₃, respectively.

In some embodiments, a11 to a13 in Formula 1 may each independently be an integer from 1 to 3.

In some embodiments, a11 to a13 in Formula 1 may each independently be an integer from 1 to 3.

In some embodiments, A₁₁ to A₁₃ in Formula 1 may each independently be a benzene group, a naphthalene group, a phenanthrene group, an anthracene group, a pyrene group, a chrysene group, or an indene group.

In some embodiments, A₁₁ to A₁₃ in Formula 1 may each independently be a benzene group.

In some embodiments, R₁₁ to R₁₄ in Formula 1 may each independently be: hydrogen; deuterium; halogen; a cyano group; a hydroxy group; an amino group; a carboxylic acid group; a thiol group; and a C₁-C₂₀ alkyl group, a C₃-C₂₀ cycloalkyl group, and a C₆-C₂₀ aryl group, each unsubstituted or substituted with deuterium, halogen, a cyano group, a hydroxyl group, an amino group, a carboxylic acid group, a thiol group, an ester moiety, a sulfonic ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₅-C₂₀ cycloalkoxy group, a C₆-C₂₀ aryl group, or a combination thereof.

In some embodiments, R₁₁ in Formula 1 may be hydrogen, deuterium, halogen, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, or CF₂CF₃.

In some embodiments, R₁₂ to R₁₄ in Formula 1 may each independently be: hydrogen; deuterium; halogen; a cyano group; a hydroxy group; an amino group; a carboxylic acid group; a thiol group; a C₁-C₂₀ alkyl group; a C₁-C₂₀ halogenated alkyl group; a C₃-C₂₀ cycloalkyl group; or a C₆-C₂₀ aryl group.

In some embodiments, two of R₁₂, R₁₃, and R₁₄ in Formula 1 adjacent to each other may be optionally bonded to each other to form a condensed ring. For example, in Formula 1, two selected from R₁₂, two selected from R₁₃, two selected from R₁₄, R₁₂ and R₁₃, R₁₃ and R₁₄, or R₁₄ and R₁₂ may be optionally bonded to each other to form a condensed ring.

In an embodiment, the first repeating unit may be represented by Formula 1-1:

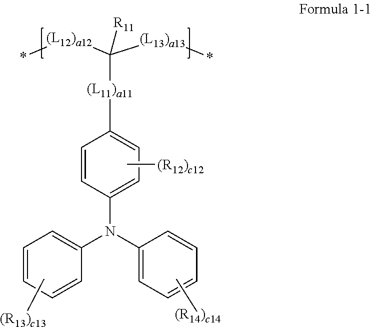

wherein, in Formula 1-1,
L₁₁ to Lis, a11 to a13, and R₁₁ to R₁₄ are the same as described above,
c₁₂ may be an integer from 1 to 4,
c₁₃ and c₁₄ may each be an integer from 1 to 5; and
* may be a binding site with an adjacent atom.

In some embodiments, the first repeating unit may be selected from Group I:

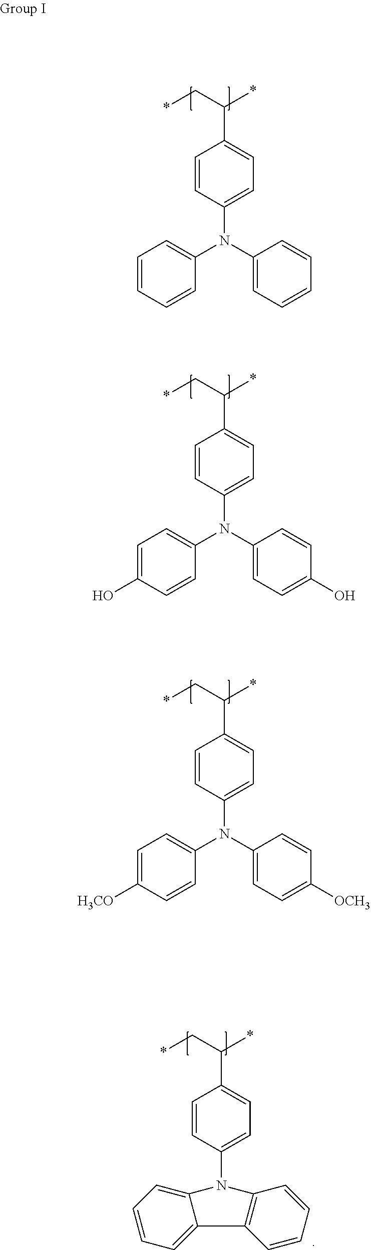

In some embodiments, the polymer may further include at least one of a second repeating unit represented by Formula 2 and a third repeating unit represented by Formula 3:

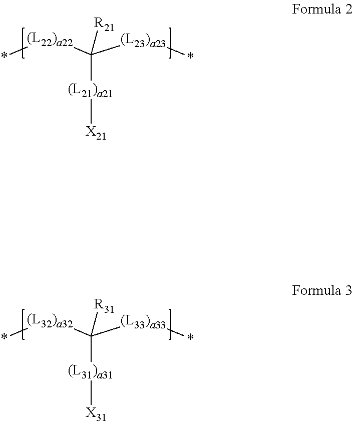

wherein, in Formulae 2 and 3,
L₂₁ to L₂₃ and L₃₁ to L₃₃ may each independently be a single bond; O; S; C(═O); C(═O)O; OC(═O); C(═O)NH; NHC(═O); or a linear, branched, or cyclic C₁-C₃₀ divalent hydrocarbon group which may optionally contain a hetero atom,
a21 to a23 and a31 to a33 may each independently be an integer from 1 to 4,
R₂₁ and R₃₁ may each independently be: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which may optionally contain a hetero atom,
X₂₁ may be an acid labile group,
X₃₁ may be a non-acid labile group, and
* may be a binding site with an adjacent atom.

In some embodiments, L₂₁ to L₂₃ and L₃₁ to L₃₃ in Formulae 2 and 3 may each independently refer to the description of L₁₁.

In some embodiments, a21 to a23 and a31 to a33 in Formulae 2 and 3 may each independently be understood by referring to the description of a11.

In some embodiments, R₂₁ and R₃₁ in Formulae 2 and 3 each independently refer to the description of R₁₁.

In some embodiments, X₂₁ in Formula 2 may be represented by Formula 5:

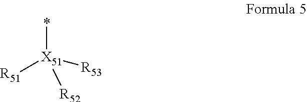

wherein, in Formula 5,
X₅₁ is a carbon atom or a silicon atom;
R₅₁ to R₅₃ may each independently be: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which may optionally contain a hetero atom,
each of R₅₁ to R₅₃ is not selected from hydrogen, deuterium, halogen, a cyano group, and an amino group,
an adjacent two of R₅₁ to R₅₃ may be optionally bonded to each other to form a condensed ring, and
* indicates a binding site to a neighboring atom.

In some embodiments, X₂₁ in Formula 2 may be selected from Formulae 6-1 to 6-12:

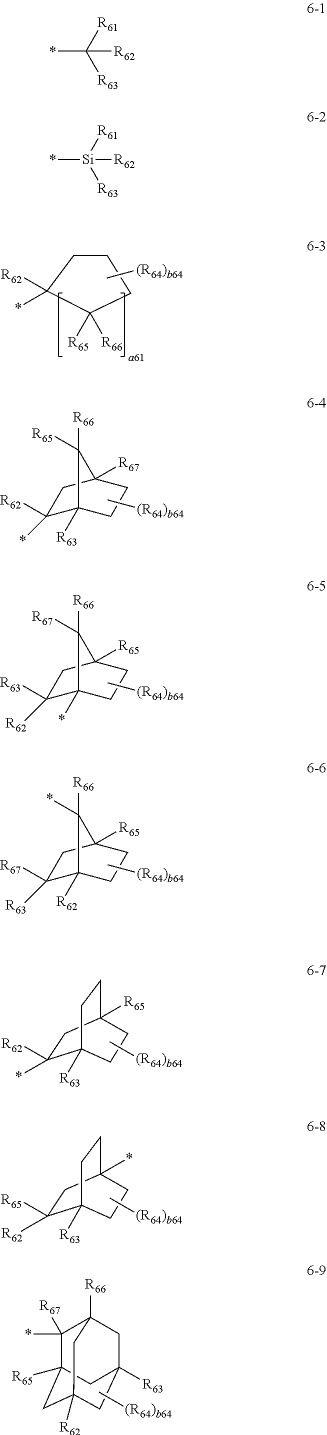

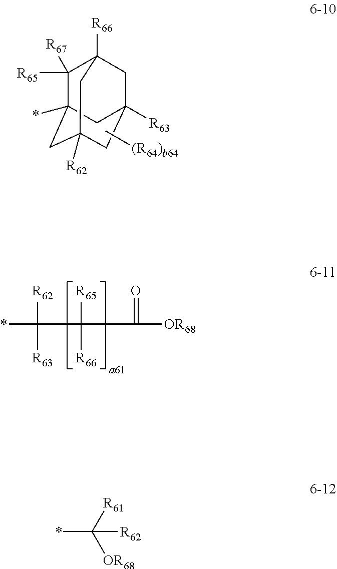

wherein, in Formulae 6-1 to 6-12,
a61 may be an integer from 0 to 6,
R₆₁ and R₆₈ may each independently be a linear, branched, or cyclic C₁-C₂₀ monovalent hydrocarbon group which may optionally contain a heteroatom,
R₆₂ to R₆₇ may each independently be: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which may optionally contain a hetero atom,
an adjacent two of R₆₁ to R₆₈ may be optionally bonded to each other to form a ring,
b64 may be an integer from 1 to 10, and
* indicates a binding site to a neighboring atom.

In some embodiments, X₂₁ in Formula 2 may be selected from Formulas 6-1 and 6-3.

When a61 in Formulae 6-3 and 6-11 is 0, (CR₆₅R₆₆)ₐ₆₁ may be a single bond.

In an embodiment, the second repeating unit may be represented by any one or two or more of Formulae 2-1 and 2-2:

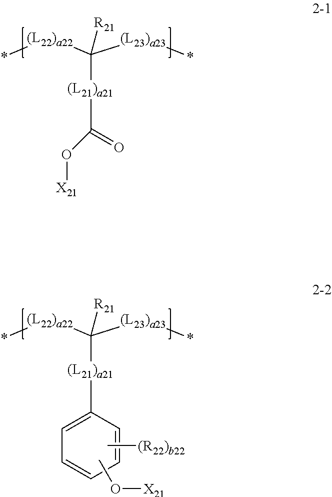

wherein, in Formulae 2-1 and 2-2,
L₂₁ to L₂₃, a21 to a23, and R₂₁ and X₂₁ are the same as described above,
R₂₂ may each independently be hydrogen; or a linear, branched, or cyclic C₁-C₃₀ monovalent hydrocarbon group which may optionally contain a heteroatom,
b22 may be an integer from 1 to 4, and
* indicates a binding site to a neighboring atom.

In some embodiments, the second repeating unit may be selected from Group II:

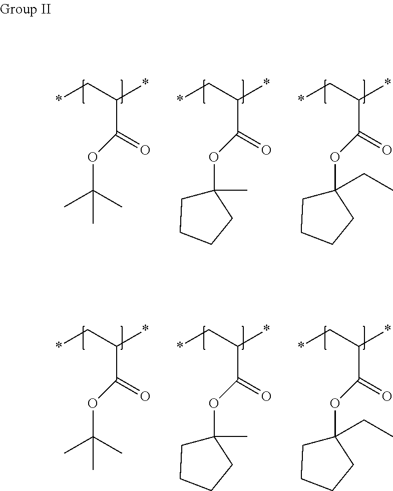

In some embodiments, X₃₁ in Formula 3 may be hydrogen; halogen; a cyano group; a hydroxy group; a carboxylic acid group; a thiol group; an amino group; or a linear, branched, or cyclic C₁-C₃₀ monovalent hydrocarbon group which may optionally contain one or more polar moieties selected from halogen, a cyano group, a hydroxyl group, a thiol group, a carboxylic acid group, O, C═O, C(═O)O, OC(═O), S(═O)O, OS(═O), a lactone moiety, a sultone moiety, and a carboxylic anhydride moiety.

In some embodiments, X₃₁ in Formula 3 may be: hydrogen; a hydroxy group; or a linear, branched, or cyclic C₁-C₃₀ monovalent hydrocarbon group containing O.

In an embodiment, the third repeating unit may be represented by any one or two or more of Formulae 3-1 and 3-2:

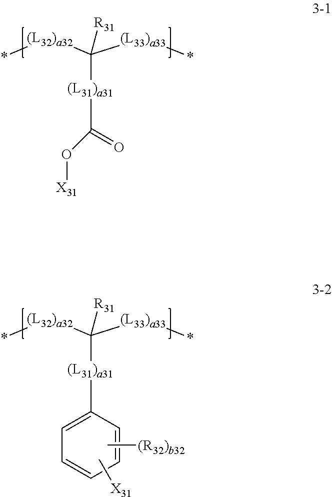

wherein, in Formulae 3-1 and 3-2,
L₃₁ to L₃₃, a31 to a33, and R₃₁ and X₃₁ are the same as described above,
R₃₂ may each independently be hydrogen; or a linear, branched, or cyclic C₁-C₃₀ monovalent hydrocarbon group which may optionally contain a heteroatom,
b32 may be an integer from 1 to 4, and
* indicates a binding site to a neighboring atom.

In some embodiments, the third repeating unit may be selected from Group III:

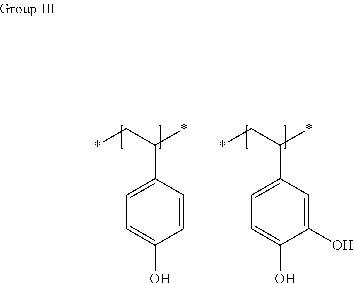

In an embodiment, the polymer may include the first repeating unit in an amount of about 1 mol % to about 100 mol %, about 5 mol % to about 100 mol %, and about 10 mol % to about 100 mol %.

For example, the polymer may include (or consist of) the first repeating unit.

In some embodiments, the polymer may include the second repeating unit in an amount of about 0 mol % to about 99 mol %, about 1 mol % to about 99 mol %, or about 10 mol % to about 90 mol %.

In some embodiments, the polymer may include the third repeating unit in an amount of about 0 mol % to about 99 mol %, about 1 mol % to about 99 mol %, or about 10 mol % to about 90 mol %.

In an embodiment, the polymer may include (or consist of) the first repeating unit and the second repeating unit. For example, the polymer may include the first repeating unit in an amount of about 1 mol % to about 99 mol % or about 10 mol % to about 90 mol %, and the second repeating unit in an amount of about 1 mol % to about 99 mol % or about 10 mol % to about 90 mol %.

In an embodiment, the polymer may include (or consist of) the first repeating unit and the third repeating unit. For example, the polymer may include the first repeating unit in an amount of about 1 mol % to about 99 mol % or about 10 mol % to about 90 mol %, and the third repeating unit in an amount of about 1 mol % to about 99 mol % or about 10 mol % to about 90 mol %.

In an embodiment, the polymer may include (or consist of) the first repeating unit, the second repeating unit, and the third repeating unit. For example, the polymer may include the first repeating unit in an amount of about 1 mol % to about 98 mol % or about 5 mol % to about 90 mol %, the second repeating unit in an amount of about 1 mol % to about 98 mol % or about 5 mol % to about 90 mol %, or the third repeating unit in an amount of about 1 mol % to about 98 mol % or about 5 mol % to about 90 mol %.

The polymer may have a weight average molecular weight (Mw) of about 1,000 to about 500,000, about 3,000 to about 100,000, or about 5,000 to about 50,000, as measured by gel permeation chromatography using a tetrahydrofuran solvent and polystyrene as a standard substance.

The polydispersity index (PDI: Mw/Mn) of the polymer may be about 1.0 to about 3.0, or about 1.0 to about 2.5. Within these ranges, the possibility of foreign matter remaining on the pattern may be lowered, or deterioration of the pattern profile may be minimized. Accordingly, the resist composition may be more suitable for forming a fine pattern.

Typically, because extreme ultraviolet (EUV) light (13.5 nm) has a lower photon count compared to ArF immersion light sources, lower exposure doses result in a significant increase in noise in the boundary region between the area illuminated by the EUV light source and the non-illuminated, unexposed area. In the case of lithography processes with EUV light sources, a higher content of photogenerators has to be used to compensate for the significant increase in noise, compared to lithography processes with other light sources of the same intensity. However, when the resist composition includes a high content of a photoacid generator, the glass transition temperature (Tg) of the base resin may change and thermal stability thereof may deteriorate. Also, the resolution of formed resist patterns may deteriorate due to a photoacid generator remaining during a lithography process using a EUV light source.

While the polymer including the first repeating unit represented by Formula 1 may generate electrons by high-energy rays, particularly EUV light sources, the photoacid generator may not directly absorb EUV light sources. In some embodiments, the polymer including the first repeating unit represented by Formula 1 may be ionized by high energy rays to generate radical cations and electrons. Subsequently, after the electrons lose some of their energy by surrounding molecules, the electrons react with a photoacid generator, and an acid may be generated from the photoacid generator. In particular, since the polymer including the first repeating unit represented by Formula 1 has a relatively high highest occupied molecular orbital (HOMO) energy level, the resist composition including the polymer may generate acids even with a relatively small amount of light, and the resolution of the resist patterns obtained therefrom may be improved.

In addition, the polymer containing the first repeating unit represented by Formula 1 may have relatively fewer restrictions on the addition amount compared to single molecules, and may provide patterns of improved quality because the polymer has appropriate solubility in developing solutions compared to single molecules.

### [Resist Composition]

According to another aspect, a resist composition including the polymer, a photoacid generator, and an organic solvent is provided. The resist composition may have improved developability and/or improved resolution.

The solubility of the resist composition in a developing solution may be changed by exposure to high energy rays. The resist composition may be a positive-type resist composition in which an exposed portion of a resist film is dissolved and removed to form a positive-type resist pattern, or a negative-type resist composition in which an unexposed portion of a resist film is dissolved and removed to form a negative-type resist pattern. In addition, the resist composition according to an embodiment may be: for an alkaline developing process using an alkaline developing solution for developing treatment when forming a resist pattern; or for a solvent developing process using a developing solution containing an organic solvent for the developing treatment (hereinafter, also referred to as an organic developing solution).

The polymer may be used in an amount of about 0.1 parts by weight to about 80 parts by weight based on 100 parts by weight of the resist composition. In some embodiments, the polymer may be used in an amount of about 1 part by weight to about 5 parts by weight based on 100 parts by weight of the resist composition. Within these ranges, the function of sensitizer is exhibited at an appropriate level, and any performance loss, for example, the formation of foreign particles due to a decrease in sensitivity and/or lack of solubility, may be reduced.

Since the polymer is as described above, other components, for example, a photoacid generator, an organic solvent, and optionally a quencher and a base resin will be described below.

### <Photoacid Generator>

The photoacid generator may be any compound capable of generating an acid when exposed to high energy rays, such as UV, DUV, EB, EUV, X-rays, α-rays, and γ-rays.

The photoacid generator may include a sulfonium salt, an iodonium salt, and a combination thereof.

In an embodiment, the photoacid generator may be represented by Formula 7:

B₇₁⁺A₇₁⁻ Formula 7
wherein, in Formula 7,
B₇₁⁺ is represented by Formula 7A,
A₇₁⁻ is represented by any of Formulae 7B to 7D, and
B₇₁⁺ and A₇₁⁻ may optionally be linked via a carbon-carbon covalent bond;

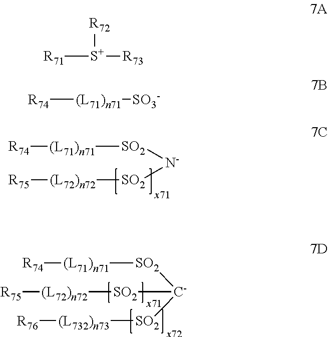

wherein, in Formulae 7A to 7D,
L₇₁ to L₇₃ may each independently be a single bond or CRR′,
R and R′ may each independently be hydrogen, deuterium, halogen, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 may each independently be 1, 2, or 3,
x71 and x72 may each independently be 0 or 1,
R₇₁ to R₇₃ may each independently be a linear, branched, or cyclic C₁-C₃₀ monovalent hydrocarbon group which may optionally contain a heteroatom,
an adjacent two of R₇₁ to R₇₃ may be optionally bonded to each other to form a condensed ring, and
R₇₄ to R₇₆ may each independently be: hydrogen; halogen; or a linear, branched, or cyclic C₁-C₃₀ monovalent hydrocarbon group which may optionally contain a heteroatom.

For example, in Formula 7, B₇₁⁺ may be represented by Formula 7A, and A₇₁⁻ may be represented by Formula 7B. In some embodiments, R₇₁ to R₇₃ in Formula 7A may each represent a phenyl group.

The photoacid generator may be included in an amount of about 0.01 parts by weight to about 40 parts by weight, about 0.1 parts by weight to about 40 parts by weight, or about 0.1 parts by weight to about 20 parts by weight, based on 100 parts by weight of the polymer. Within these ranges, appropriate levels of resolution may be achieved, and problems related to foreign matter particles after development or during stripping may be reduced.

One type of photoacid generator may be used, or two or more different types thereof may be mixed and used.

### <Organic Solvent>

The organic solvent included in the resist composition is not particularly limited as long as the organic solvent is capable of dissolving or dispersing components that are included according to purpose, including the polymer, the photoacid generator, and optionally included quencher. As the organic solvent, one type of an organic solvent may be used, or two or more different types of organic solvents may be used in combination. In addition, a mixed solvent in which water and an organic solvent are mixed may be used.

Examples of the organic solvent are an alcohol-based solvent, an ether-based solvent, a ketone-based solvent, an amide-based solvent, an ester-based solvent, a sulfoxide-based solvent, a hydrocarbon-based solvent, and the like.

Examples of the alcohol-based solvent are: a monoalcohole-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyhydric alcohol-based solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and a polyhydric alcohol-containing ether solvent, such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether.

Examples of the ether-based solvent are a dialkyl ether-based solvent such as diethyl ether, dipropyl ether, dibutyl ether, diethylene glycol dimethyl ether, or propylene glycol dimethyl ether, a cyclic ether-based solvent such as tetrahydrofuran or tetrahydropyran, and an aromatic ring-containing ether-based solvent such as diphenyl ether or anisole.

Examples of the ketone-based solvent are a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone, a cyclic ketone-based solvent such as cyclopentanone, cyclohexanone, cycloheptanone, cyclooctanone, or methylcyclohexanone, 2,4-pentanedione, acetonyl acetone, and acetophenone.

Examples of the amide-based solvent are a cyclic amide-based solvent such as N, N′-dimethylimidazolidinone or N-methyl-2-pyrrolidone, and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent are: an acetate ester-based solvent, such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyhydric alcohol-containing ether carboxylate-based solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA) propylene glycol monoethyl ether acetate, propylene glycol monopropyl ether acetate, propylene glycol monobutyl ether acetate, dipropylene glycol monomethyl ether acetate, and dipropylene glycol monoethyl ether acetate; a lactone solvent, such as γ-butyrolactone and δ-valerolactone; a carbonate-based solvent, such as dimethyl carbonate, diethyl carbonate, ethylene carbonate, and propylene carbonate; and a lactate ester-based solvent, such as methyl lactate, ethyl lactate, n-butyl lactate, and n-amyl lactate; glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvent are dimethyl sulfoxide and diethyl sulfoxide.

Examples of the hydrocarbon-based solvent are an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane, and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

In some embodiments, the organic solvent may be selected from an alcohol-based solvent, an amide-based solvent, an ester-based solvent, a sulfoxide-based solvent, and a combination thereof. In some embodiments, the organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and a combination thereof.

In some embodiments, when an acid labile group in the form of acetal is used, the organic solvent may further include a high-boiling alcohol to accelerate the deprotection reaction of the acetal. Examples of the high-boiling alcohol are diethylene glycol, propylene glycol, glycerol, 1,4-butanediol, and 1,3-butanediol.

The organic solvent may be used in an amount of about 200 parts by weight to about 20,000 parts by weight, or about 2,000 parts by weight to about 10,000 parts by weight, based on 100 parts by weight of the polymer.

### <Quencher>

The resist composition may further include a quencher.

The quencher may be a salt that generates an acid that is less acidic than the acid generated from the photoacid generator.

The quencher may include an ammonium salt, a sulfonium salt, an iodonium salt, and a combination thereof.

In an embodiment, the quencher may be represented by Formula 8:

B₈₁⁺A₈₁⁻ Formula 8
wherein, in Formula 8,
B₈₁⁺ may be represented by any one of the Formulae 8A to 8C, A₈₁⁻ may be represented by any one of Formulae 8D to 8F, and
B₈₁⁺ and A₈₁⁻ may optionally be linked via a carbon-carbon covalent bond,

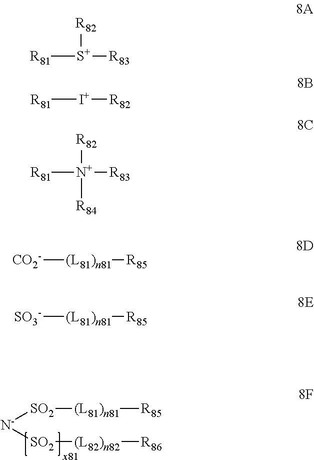

wherein, in Formulae 8A to 8F,
L₈₁ and L₈₂ may each independently be a single bond or CRR′,
R and R′ may each independently be hydrogen, deuterium, halogen, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 may each independently be 1, 2, or 3,
x81 may be 0 or 1,
R₈₁ to R₈₄ may each independently be a linear, branched, or cyclic C₁-C₃₀ monovalent hydrocarbon group which may optionally contain a heteroatom,
an adjacent two of R₈₁ to R₈₄ may be optionally bonded to each other to form a condensed ring, and
R₈₅ and R₈₆ may each independently be: hydrogen; halogen; or a linear, branched, or cyclic C₁-C₃₀ monovalent hydrocarbon group which may optionally contain a heteroatom.

The quencher may include about 0 parts by weight to about 10 parts by weight, about 0.05 parts by weight to about 5 parts by weight, or about 0.1 parts by weight to about 3 parts by weight, based on 100 parts by weight of the polymer. Within these ranges, appropriate levels of resolution may be achieved, and problems related to foreign matter particles after development or during stripping may be reduced.

One type of quencher may be used, or two or more different types thereof may be mixed and used.

### <Base Resin>

The resist composition may further include a base resin.

The base resin may include a repeating unit that contains an acid labile group and is represented by Formula 2:

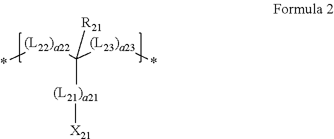

wherein, in Formula 2,
L₂₁ to L₂₃ may each independently be a single bond; O; S; C(═O); C(═O)O; OC(═O); C(═O)NH; NHC(═O); or a linear, branched, or cyclic C₁-C₃₀ divalent hydrocarbon group which may optionally contain a hetero atom,
a21 to a23 may each independently be an integer from 1 to 4,
R₂₁ may be: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which may optionally contain a hetero atom,
X₂₁ may be an acid labile group, and
* may be a binding site with an adjacent atom.

Formula 2 may be the same as described above.

The base resin containing the repeating unit represented by Formula 2 is decomposed under the action of an acid to generate a carboxyl group, thereby being converted into alkali-soluble.

In addition to the repeating unit represented by Formula 2, the base resin may further include a repeating unit represented by Formula 3:

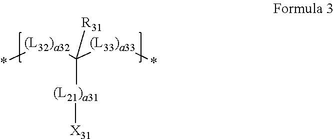

wherein, in Formula 3,
L₃₁ to L₃₃ may each independently be a single bond; O; S; C(═O); C(═O)O; OC(═O); C(═O)NH; NHC(═O); or a linear, branched, or cyclic C₁-C₃₀ divalent hydrocarbon group which may optionally contain a hetero atom,
a11 to a13 may each independently be an integer from 1 to 4;
R₃₁ may be: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which may optionally contain a hetero atom,
X₃₁ may be a non-acid labile group, and
* may be a binding site with an adjacent atom.

Formula 3 may be the same as described above.

For example, in the case of ArF lithography processes, X₃₁ may contain a lactone ring as a polar moiety, and in the case of KrF, EB, and EUV lithography processes, X₃₁ may contain a phenol.

In an embodiment, the base resin may further include a moiety containing an anion and/or a cation. For example, the base resin may further include a moiety that is derived to allow a photoacid generator and/or a quencher to bind to a side chain.

The base resin may have a weight average molecular weight (Mw) of about 1,000 to about 500,000, or about 3,000 to about 100,000, as measured by gel permeation chromatography using a tetrahydrofuran solvent and polystyrene as a standard substance.

The PDI (Mw/Mn) of the base resin may be about 1.0 to about 3.0, or about 1.0 to about 2.0. Within these ranges, the possibility of foreign matter remaining on the pattern may be lowered, or deterioration of the pattern profile may be minimized. Accordingly, the resist composition may be more suitable for forming a fine pattern.

The base resin may be prepared by any suitable method, for example, by dissolving unsaturated bond-containing monomer(s) in an organic solvent and then thermally polymerizing in the presence of a radical initiator.

Regarding the base resin, the mole fraction (mol %) of each repeating unit derived from each monomer is as follows, but is not limited thereto:
i) inclusion of about 1 mol % to about 60 mol %, or, about 5 mol % to about 50 mol %, or, about 10 mol % to about 50 mol % of the repeating unit represented by Formula 2; and
ii) inclusion of about 40 mol % to about 99 mol %, or, about 50 mol % to about 95 mol %, or, about 50 mol % to about 90 mol % of the repeating unit represented by Formula 3.

The base resin may be a single polymer or may include a mixture of two or more polymers having different compositions, weight average molecular weights and/or polydispersity indexes.

### <Any Components>

The resist composition may further include a surfactant, a crosslinking agent, a leveling agent, a colorant, or a combination thereof as necessary.

The resist composition may further include a surfactant to improve coatability, developability, and the like. Example of the surfactant are a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant are KP341 (manufactured by Shin-Etsu Chemical Co., Ltd.), Polyflow No. 75 and Polyflow No. 75 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), FLUORAD™ FC430 and FLUORAD™ FC431 (manufactured by Sumitomo 3M, Ltd.), ASAHI GUARD™ AG710 (manufactured by AGC Seimi Chemical Co., Ltd.), and SURFLON™ S-382, SURFLON™ SC-101, SURFLON™ SC-102, SURFLON™ SC-103, SURFLON™ SC-104, SURFLON™ SC-105, and SURFLON™ SC-106 (manufactured by AGC Seimi Chemical Co., Ltd.).

The surfactant may be included in a range of about 0 parts by weight to about 20 parts by weight with respect to about 100 parts by weight of the polymer.

As the surfactant, one type of a surfactant may be used, or two or more different types of surfactants may be mixed and used.

A method of preparing the resist composition is not particularly limited, and for example, a method of mixing a polymer, a photoacid generator, and optional components added as needed in an organic solvent, may be used. A temperature or time during mixing is not particularly limited. If necessary, filtration may be performed after mixing.

### [Pattern Forming Method]

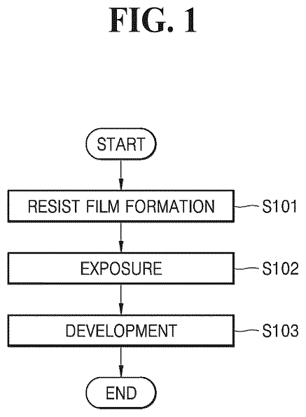

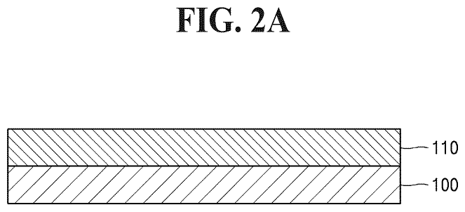

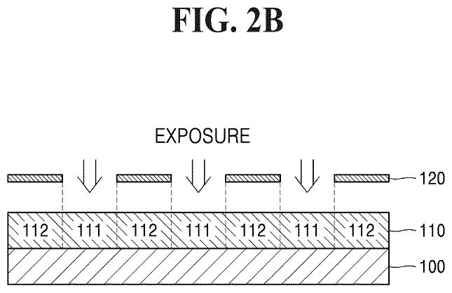

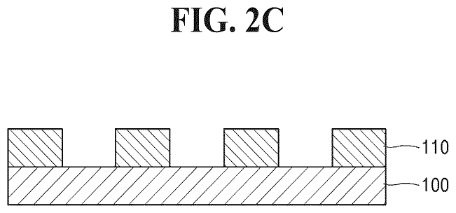

Hereinafter, a pattern forming method according to embodiments will be described in more detail with reference to FIGS. 1 and 2A to 2C. FIG. 1 is a flowchart illustrating the pattern forming method according to embodiments, and FIG. 2 is a side cross-sectional view illustrating the pattern forming method according to embodiments. Hereinafter, a pattern forming method using a positive resist composition will be described as an example, but is not limited thereto.

Referring to FIG. 1, the pattern forming method may include operation S101 of applying a resist composition to form a resist film, operation S102 of exposing at least a portion of the resist film to high energy rays, and operation S103 of developing the exposed resist film using a developing solution. Such operations may be omitted if necessary, or may be performed in a different order.

First, a substrate 100 may be prepared. The substrate 100 may include, for example, a semiconductor substrate such as a silicon substrate or a germanium substrate, glass, quartz, ceramic, or copper. In some embodiments, the substrate 100 may include a Group III-Group V compound such as GaP, GaAs, GaSb, or the like.

A resist composition may be applied to a desired thickness on the substrate 100 by, for example, coating, to form a resist film 110. When needed, heating (referred to as pre-bake (PB) or post-annealing bake (PAB) may be performed to remove an organic solvent remaining in the resist film 110.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. In some embodiments, the resist film 110 may have a thickness of about 10 nm to about 300 nm. In some embodiments, the resist film 110 may have a thickness of about 30 nm to about 200 nm.

The lower limit of the temperature of PB may be 60° C. or more or 80° C. or more. In some embodiments, the upper limit of the temperature of PB may be 150° C. or less, or 140° C. or less. The lower limit of the time of PB may be 5 seconds or more, or 10 seconds or more. The upper limit of the time of the PB may be 600 seconds or less or 300 seconds or less.

Before the applying of the resist composition on the substrate 100, an etching target film (not shown) may be further formed on the substrate 100. The etching target film may refer to a layer on which an image is transferred from a resist pattern and converted into a certain pattern. In an embodiment, the etching target film may be formed to include, for example, an insulating material such as silicon oxide, silicon nitride, or silicon oxynitride. In some embodiments, the etching target film may be formed to include a conductive material such as a metal, metal nitride, metal silicide, or metal silicide nitride. In some embodiments, the etching target film may be formed to include a semiconductor material such as polysilicon.

In an embodiment, an antireflection film may be further formed on the substrate 100 to maximize the efficiency of a resist. The antireflection film may be an organic or inorganic antireflection film.

In an embodiment, a protective film may be further provided on the resist film 110 to reduce the influence of alkaline impurities or the like included during a process. When immersion exposure is performed, for example, a protective film for immersion may also be provided on the resist film 100 to avoid direct contact between an immersion medium and the resist film 110.

Next, at least a portion of the resist film 110 may be exposed to high energy rays. For example, high energy rays passing through a mask 120 may be irradiated onto at least a portion of the resist film 110. For this reason, the resist film 110 may have an exposed portion 111 and an unexposed portion 112.

During the exposure, the polymer may be ionized to generate radical cations and electrons.

In some cases, the exposure may be performed by irradiating high energy rays through a mask with a certain pattern using a liquid such as water as a medium. Examples of the high energy rays may include electromagnetic waves such as UV rays, deep ultraviolet (DUV) rays, extreme ultraviolet (EUV) rays (with a wavelength of 13.5 nm), X-rays, and γ-rays, and charged particle beams such as electron beams (EBs) and α rays, and the like. Irradiating the high energy rays may be collectively referred to as “exposure.”

As the method using the exposure light source, various methods may be used including: emitting laser light in the ultraviolet light region, such as KrF excimer lasers (wavelength 248 nm), ArF excimer lasers (wavelength 193 nm), and F2 excimer lasers (wavelength 157 nm); emitting harmonic laser light in the subatomic or vacuum subatomic region by converting wavelength-shifting laser light from solid-state laser sources (such as YAG or semiconductor lasers); and irradiating electrons or ultraviolet (EUV) light. During exposure, the exposure may be usually performed through a mask corresponding to a desired pattern, but when exposure light is an electron beam, the exposure may be performed through direct writing without using a mask.

The integrated dose of high-energy rays is, for example, when ultra-ultraviolet rays are used as the high-energy rays, the integrated dose may be 2000 mJ/cm² or less, or 500 mJ/cm² or less. In addition, when EBs are used as the high energy rays, the integral dose may be 5,000 μC/cm² or less, or 1,000 μC/cm² or less.

In addition, post-exposure bake (PEB) may be performed after the exposure. The lower limit of the temperature of PEB may be 50° C. or more or 80° C. or more. The upper limit of the temperature of PEB may be 180° C. or less or 130° C. or less. The lower limit of the time of the PEB time may be 5 seconds or more or 10 seconds or more. The upper limit of the time of the PEB may be 600 seconds or less or 300 seconds or less.

Next, the exposed resist film 110 may be developed using a developing solution. The exposed portion 111 may be washed away by the developing solution, and the unexposed portion 112 remains without being washed away by the developing solution.

Examples of the developing solution are an alkaline developing solution and a developing solution including an organic solvent (hereinafter also referred to as “organic developing solution”). Examples of a developing method are a dipping method, a puddle method, a spray method, a dynamic injection method, and the like. A developing temperature may be, for example, 5° C. or more and 60° C. or less, and a developing time may be, for example, 5 seconds or more and 300 seconds or less.

The alkaline developing solution may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, TMAH, pyrrole, piperidine, choline, 1,8-diazabicyclo[5.4.0]-7-undecene (DBU), and 1,5-diazabicyclo[4.3.0]-5-nonene (DBN) are dissolved. The alkali developing solution may further include a surfactant.

The lower limit of the amount of the alkaline compound in the alkaline developing solution may be 0.1% by mass or more, or 0.5% by mass or more, or 1% by mass or more. In some embodiments, the upper limit of the content of the alkaline compound in the alkaline developing solution may be 20% by mass or less, or 10% by mass or less, or 5% by mass or less.

After development, the resist pattern may be washed with ultrapure water, and then water remaining on the substrate and pattern may be removed therefrom.

Examples of the organic solvent included in the organic developing solution may include the same organic solvents as those exemplified in the part of <Organic solvent> of [Resist composition].

The lower limit of the amount of the organic solvent in the organic developing solution may be 80% by mass or more, or 90% by mass or more, or 95% by mass or more, or 99% by mass or more.

The organic developing solution may also include a surfactant. In addition, a trace amount of water may be included in the organic developing solution. In some embodiments, during development, development may be stopped by substituting with a different kind of solvent from the organic developing solution.

The resist pattern after the development may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate 100 and the resist pattern may be removed. In addition, when the ultrapure water is used, water remaining on the substrate 100 and the resist pattern may be removed.

In addition, developing solutions may be used singly or in a combination of two or more.

After the resist pattern is formed as described above, a pattern interconnection substrate may be obtained through etching. The etching may be performed through a known method including dry etching using a plasma gas and wet etching using an alkaline solution, a copper (II) chloride solution, an iron (II) chloride solution, or the like.

After the resist pattern is formed, plating may be performed. The plating is not particularly limited, and examples thereof may include copper plating, solder plating, nickel plating, gold plating, and the like.

The resist pattern remaining after the etching may be peeled off with an organic solvent. One or more embodiments are not limited thereto, but examples of such an organic solvent may include PGMEA, PGME, ethyl lactate (EL), and the like. A peeling method is not particularly limited, but examples thereof may include an immersion method, a spray method, and the like. In addition, the interconnection substrate on which the resist pattern is formed may be a multilayer interconnection substrate or may have small-diameter through-holes.

In an embodiment, the interconnection substrate may be formed through a method of forming a resist pattern, depositing a metal in a vacuum, and then melting the resist pattern with a solution, that is, a lift-off method.

The disclosure will be described in more detail using the following Examples and Comparative Examples, but the technical scope of inventive concepts in the present disclosure is not limited only to the following Examples.

### EXAMPLES

### Synthesis Example 1: Synthesis of Polymer P-1

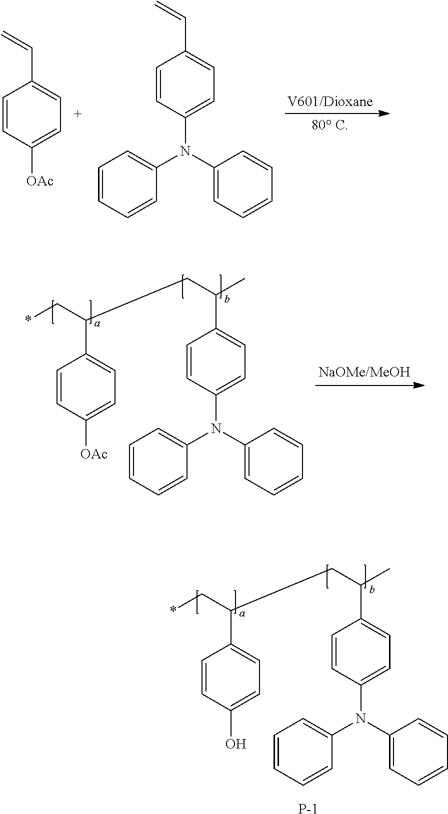

1.22 g (0.007 mol) of 4-acetoxy styrene (AHS), which is Monomer 1, and 1.878 g (0.007 mol) of 4-vinylphenyldiphenylamine (TPA), which is Monomer 2, were added to a 100 ml reactor. Then, 0.159 g of V601 was added thereto as an initiator, and 7 g of 1,4-dioxane was added thereto as a solvent. The reactants were bubbled with nitrogen and the reactor was sealed and reacted at 80° C. for 4 hours. The reaction was completed, precipitated with methanol, and filtered to obtain a precipitate. The precipitate was dried in a 40° C. vacuum oven. 2 g of the dried polymer was dispersed in 16 g of methanol, and then, 1.8 g of a sodium methoxide solution (25 wt %, methanol) was added thereto. Reaction was quenched in water after at least 4 hours at room temperature. The resultant mixture was neutralized with acetic acid and extracted with ethyl acetate. The collected organic layers were washed with water, dried using sodium sulfate, and filtered, and the resultant solution was precipitated using 400 ml of hexane to obtain a precipitate. The precipitate was dried, thereby obtaining 1.2 g (yield 40%) of the final product polymer P-1. With respect to the obtained polymer, the weight average molecular weight was 13,617 g/mol and the PDI was 2.34.

### Synthesis Examples 2 to 7 and Comparative Synthesis Examples 1 to 2

The same methods as in Synthesis Example 1 were used except for using Monomers 1 to 3 in Table 2 below instead of Monomers 1 and 2.

TABLE 1

| | | Monomer | | | Monomer ratio (mol %) | | | | |
|---|---|---|---|---|---|---|---|---|---|
| | Name of | Mono- | Mono- | Mono- | Mono- | Mono- | Mono- | Molecular | |
| | polymer | mer 1 | mer 2 | mer 3 | mer 1 | mer 2 | mer 3 | weight | PDI |
| Comparative | A | PHS | MCPA | — | 50 | 50 | — | 5,435 | 1.42 |
| Synthesis | | | | | | | | | |
| Example 1 | | | | | | | | | |
| Synthesis | P-1 | PHS | TPA | — | 50 | 50 | — | 13,617 | 2.34 |
| Example 1 | | | | | | | | | |
| Synthesis | P-2 | PHS | TPA | ECPA | 50 | 10 | 40 | 11,694 | 2.12 |
| Example 2 | | | | | | | | | |
| Synthesis | P-3 | PHS | TPA | ECPA | 40 | 20 | 40 | 12,020 | 2.07 |
| Example 3 | | | | | | | | | |
| Synthesis | P-4 | PHS | TPA | MCPA | 45 | 5 | 50 | 5,484 | 1.98 |
| Example 4 | | | | | | | | | |
| Synthesis | P-5 | PHS | TPA | MCPA | 55 | 5 | 40 | 5,553 | 1.97 |
| Example 5 | | | | | | | | | |
| Synthesis | P-6 | PHS | TPA | MCPA | 60 | 5 | 35 | 5,347 | 2.05 |
| Example 6 | | | | | | | | | |
| Synthesis | P-7 | DHS | TPA | MCPA | 50 | 20 | 30 | 9,192 | 2.45 |
| Example 7 | | | | | | | | | |
| Synthesis | P-8 | DHS | TPA | MCPA | 45 | 20 | 35 | 11,796 | 1.88 |
| Example 8 | | | | | | | | | |
| Synthesis | P-9 | DHS | TPA | MCPA | 35 | 20 | 45 | 11,974 | 1.53 |
| Example 9 | | | | | | | | | |
| Synthesis | P-10 | DHS | TPA | MCPA | 40 | 10 | 60 | 15,312 | 1.71 |
| Example 10 | | | | | | | | | |

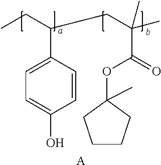

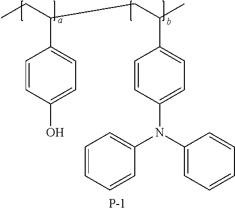

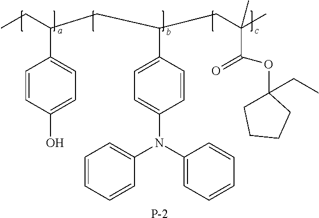

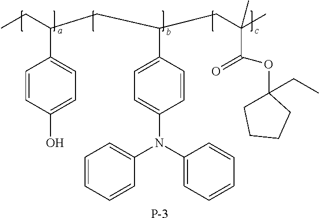

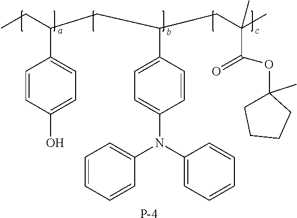

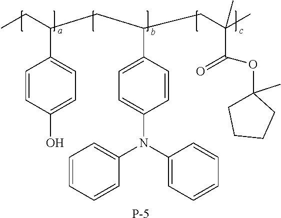

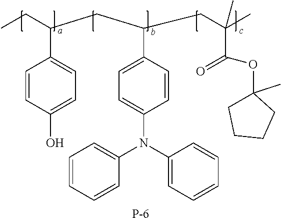

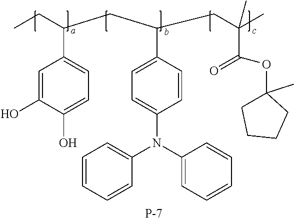

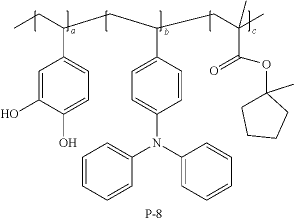

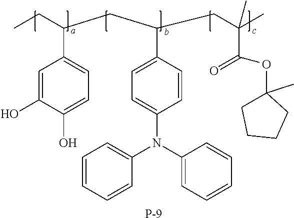

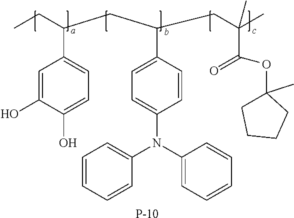

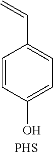

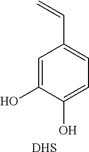

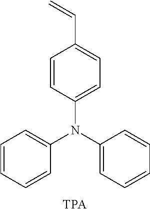 [SMILES: C=Cc1ccc(N(c2ccccc2)c2ccccc2)cc1]

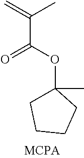

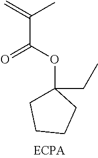

### Evaluation Example 1: Acid Generation Rate Evaluation

10 wt % of the polymer shown in Table 2 below, 1 wt % of PAG A, which is a photoacid generator, and 6.5 wt % of Coumarin 6 (CAS No. 38215-36-0) were dissolved in cyclohexanone. The obtained solution was spin coated on a 1 inch×1 inch quartz plate to a thickness of 400 nm and dried at 130° C. for 2 minutes to form a thin film. The thin film was exposed to 5 to 50 mJ/cm² of DUV (248 nm), and then, absorbance thereof was measured. After exposure to 10 mJ/cm² of DUV, the value obtained by dividing the absorbance measured at 535 nm by the absorbance measured at 475 nm (OD_{535 nm}/OD_{475 nm}), was normalized and shown in Table 2 and as acid generation rates. Theoretically, the absorbance of coumarin 6 is increased at a wavelength of 535 nm by acid generation. Accordingly, coumarin 6 was used as an acid indicator.

TABLE 2

| | | OD₅₃₅ₙₘ/OD₄₇₅ₙₘ |
|---|---|---|
| | Name of polymer | (@ DUV 10 mJ/cm²) |
| Comparative Example 1-1 | A | 0.11 |
| Example 1-1 | P-1 | 0.23 |
| Example 1-2 | P-2 | 0.62 |
| Example 1-3 | P-3 | 0.71 |
| Example 1-4 | P-4 | 0.52 |
| Example 1-5 | P-5 | 0.51 |
| Example 1-6 | P-6 | 0.55 |
| Example 1-7 | P-7 | 0.63 |
| Example 1-8 | P-8 | 0.63 |
| Example 1-9 | P-9 | 0.62 |
| Example 1-10 | P-10 | 0.57 |

<PAG A>

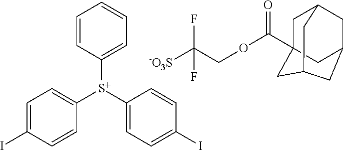

Referring to Table 2, it can be seen that Examples 1-1 to 1-10 have an increased acid generation rate compared to Comparative Example 1-1. That is, it can be expected that using the polymers of Synthesis Examples 1 to 10 can provide more improved resolution than the case of using the polymer of Comparative Synthesis Example 1 even if the same amount of photoacid generator is used.

### Evaluation Example 2: Photofragment Velocity Evaluation

Each of the polymers listed in Table 3 was dissolved in an amount of 3 wt % in a 7/3 (wt/wt) solution of propylene glycol methyl ether/propylene glycol methyl ether acetate (PGME/PGMEA), and PAG A was dissolved in an amount of 2 wt % in the casting solvents. The casting solution was spin-coated at 1500 rpm on a silicon wafer having thereunder a lower film including HMDS and having the thickness of 3 nm, and then dried at 130° C. for 1 minute to prepare a film having an initial thickness shown in Table 3 below. Then, the films having the initial thickness of Table 3, was exposed to 254 nm-wavelength DUV or 13.5 nm-wavelength EUV at a dose of 0 to 50 mJ/cm², and post-exposure bake was performed at 90° C. for 60 seconds. Then, after dissolving the exposed part in tetrahydrofuran, the weight of the remaining PAG A was analyzed by HPLC, and the decomposition rate constant (k) was determined by normalizing the same based on the initial PAG A weight. Results are shown in Table 3.

TABLE 3

| | | | Decomposition |
|---|---|---|---|
| | Name of | Decomposition rate constant | rate constant |
| | polymer | (DUV) | (EUV) |
| Comparative Example 2-1 | A | 0.12 | 0.07 |
| Example 2-1 | P-1 | 0.22 | 0.08 |
| Example 2-2 | P-2 | 0.23 | 0.08 |
| Example 2-3 | P-3 | 0.25 | 0.08 |
| Example 2-4 | P-4 | 0.21 | 0.12 |
| Example 2-5 | P-5 | 0.21 | 0.09 |
| Example 2-6 | P-6 | 0.23 | 0.08 |
| Example 2-7 | P-7 | 0.26 | 0.09 |
| Example 2-8 | P-8 | 0.24 | 0.09 |
| Example 2-9 | P-9 | 0.26 | 0.10 |
| Example 2-10 | P-10 | 0.21 | 0.08 |

<PAG A>

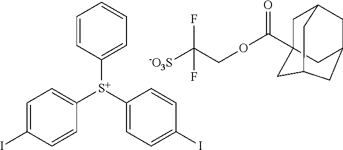

Referring to Table 3, it can be seen that the k value of Examples 2-1 to 2-10 is greater than the k value of Comparative Example 2-1. In other words, it is expected that when the polymers of Synthesis Examples 1 to 10 are used, the photoacid generator decomposition rate is faster, and even if the same amount of photoacid generator is used, the improved resolution can be provided than when the polymer of Comparative Synthesis Example 1 is used.

### Evaluation Example 3: Evaluation of Thin Film Development

### (1) Terminology

Eₜₕ refers to an exposure dose at a time point at which a thin film starts to be cured, and E₁ refers to an exposure dose at a saturation point at which a thickness of the thin film does not become increased. A remaining film ratio is a value, which is obtained by dividing a thin film thickness at a saturation point by an initial thickness, and is expressed as a percentage, and γ is a contrast curve and is a value calculated by Equation 1 below:

$$γ = {\vert log ( \frac{{E}_{th}}{{E}_{1}} ) \vert}^{- 1} \qquad Equation 1$$

NRT stands for normalized remaining thickness.

### (2) Evaluation of Thin Film Development

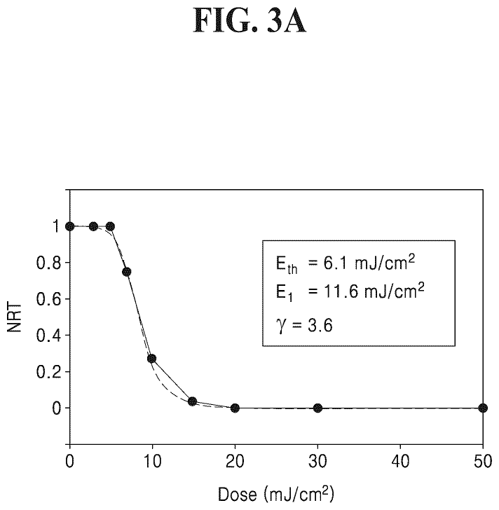

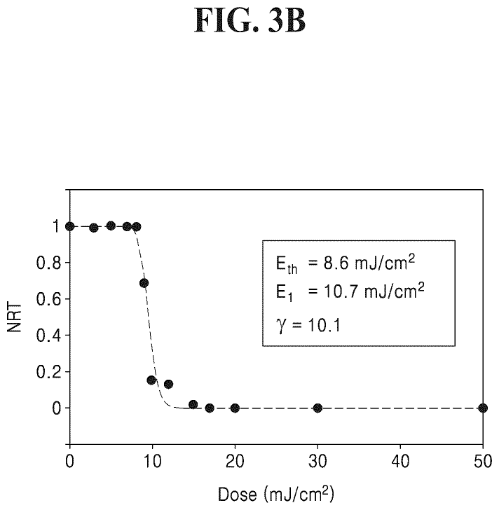

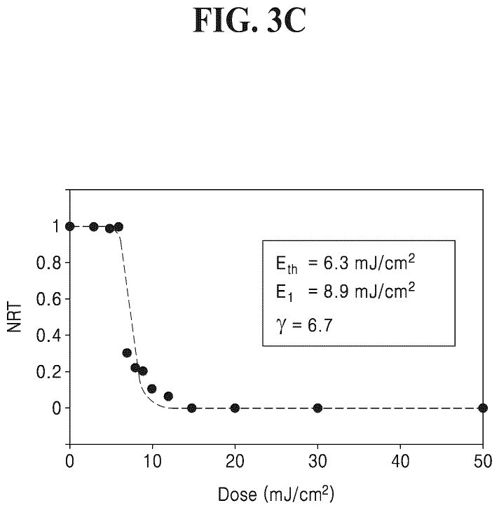

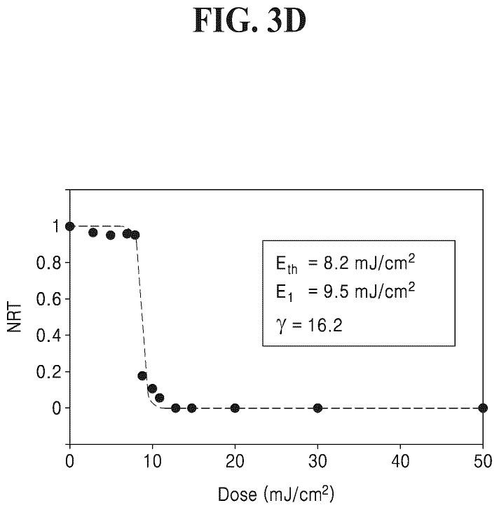

Each of the polymers listed in Table 4 was dissolved in an amount of 3 wt % in a 7/3 (wt/wt) solution of propylene glycol methyl ether/propylene glycol methyl ether acetate (PGME/PGMEA), and PAG A and PDQ A listed in Table 4 were dissolved in an amount of 2 wt % in the casting solvents listed in Table 4. In this regard, the weight ratios of the polymer, PAG A and PDQ A are as shown in Table 4 below. The casting solution was spin-coated at 1500 rpm on a silicon wafer having thereunder a lower film including HMDS and having the thickness of 3 nm, and then dried at 130° C. for 1 minute to prepare a film having an initial thickness shown in Table 4 below. Then, the films having the initial thickness of Table 4 were exposed to 254 nm-wavelength DUV at a dose of 0 to 50 mJ/cm², followed by post-exposure bake at 90° C. for 60 seconds, and then, the development was performed using 2.38 wt % TMAH aqueous solution at room temperature for 60 seconds, and then, the thickness of the remaining coating layer was measured using a three-dimensional optical profiler (Bruker, Contour X-100), and is shown in Table 4 and FIGS. 3A to 3D. FIG. 3A is a graph showing data of Comparative Example 3-1, FIG. 3B is a graph showing data of Example 3-1, FIG. 3C is a graph showing data of Example 3-2, and FIG. 3D is a graph showing data of Example 3-3.

TABLE 4

| | | Weight ratio | | Initial | | | | |
|---|---|---|---|---|---|---|---|---|
| | | (Polymer: PAG | PAB | thickness | PEB | ETH | E1 | |
| | Polymer | A: PDQ A, wt %) | (° C.) | (nm) | (° C.) | (mJ) | (mJ) | g |
| Comparative | A | 2:3:2 | 120 | 101 | 90 | 6.1 | 11.6 | 3.6 |
| Example 3-1 | | | | | | | | |
| Example 3-1 | P-8 | 2:3:2 | 120 | 97 | 90 | 8.6 | 10.7 | 10.1 |
| Example 3-2 | P-9 | 2:3:2 | 120 | 97 | 90 | 6.3 | 8.9 | 6.7 |
| Example 3-3 | P-10 | 2:3:2 | 120 | 103 | 90 | 8.2 | 9.2 | 16.2 |

<PAG A> 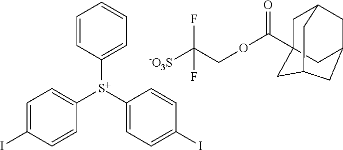
<PDQ A>

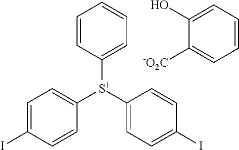

Referring to Table 4, it can be seen that Examples 3-1 to 3-3 exhibit a smaller E₁ value and a larger γ value than Comparative Example 3-1, which indicates that Examples 3-1 to 3-3 have improved sensitivity than Comparative Example 3-1.

Examples of the present disclosure may provide a resist composition that may provide improved sensitivity and/or resolution.

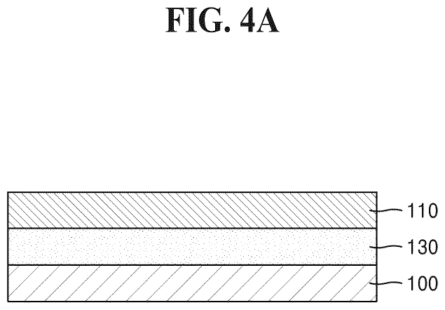

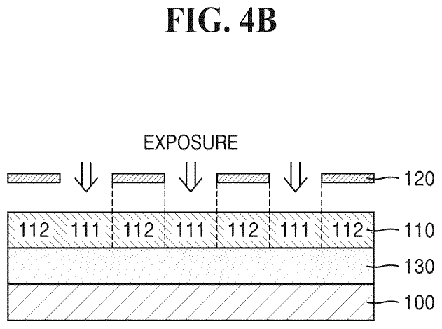

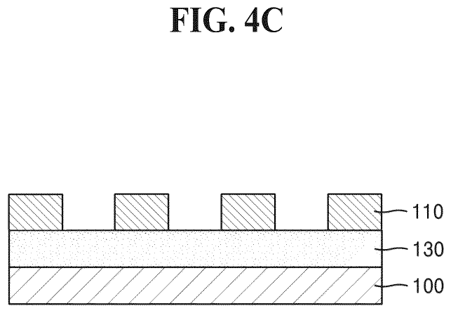

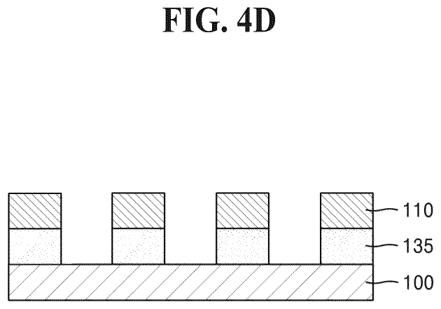

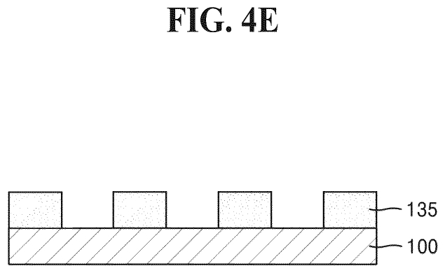

FIGS. 4A to 4E are side cross-sectional views illustrating a method of forming a patterned structure according to an embodiment.

Referring to FIG. 4A, a material layer 130 may be formed on the substrate 100 before forming a resist film 110 on the substrate 100. The resist film 110 may be formed on top of the material layer 130. The material layer 130 may include an insulating material (e.g., silicon oxide, silicon nitride), a semiconductor material (e.g., silicon), a metal (e.g., copper). In some embodiments, the material layer 130 may be a multi-layer structure. A material of the material layer 130 may be different than a material of the substrate 100. The resist film 110 may include a resist composition according to example embodiments. The resist film 110 may include a photoacid generator, an organic solvent, and optionally a quencher and a base resin.

Referring to FIG. 4B, the resist film 110 may undergo a pre-exposure bake process and may be exposed with high energy rays through a mask 120, after which the resist film 110 may include exposed regions 111 and unexposed regions 112.

Referring to FIG. 4C, the exposed resist film 110 may be developed using a developer (e.g., developing solution). The exposed area 111 may be washed away by the developer, whereas the unexposed area 112 may remain without being washed away by the developer.

Referring to FIG. 4D, exposed areas of the material layer 130 may be etched using the resist pattern 110 as a mask to form a material pattern 135 on the substrate 100.

Referring to FIG. 4E, the resist pattern 110 may be removed.

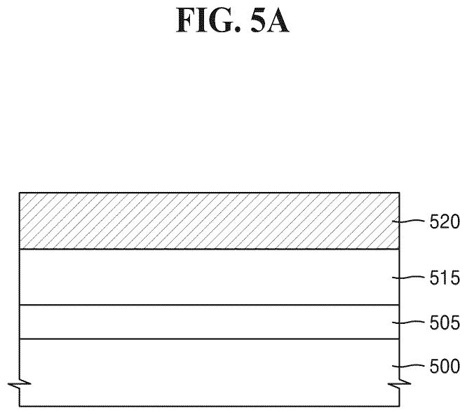

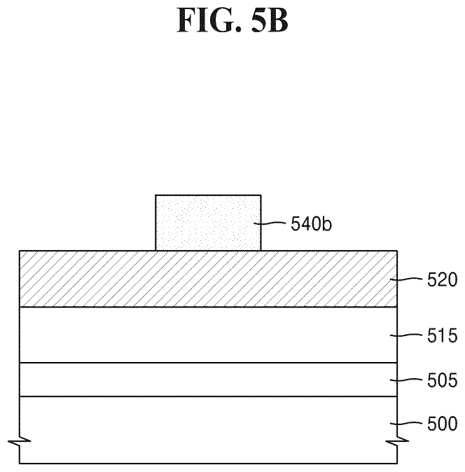

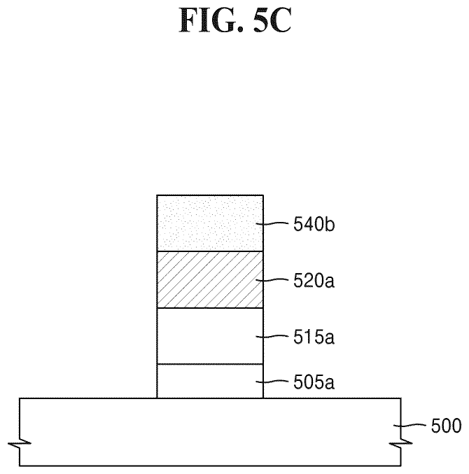

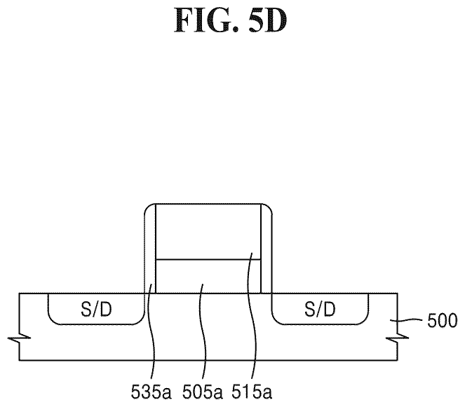

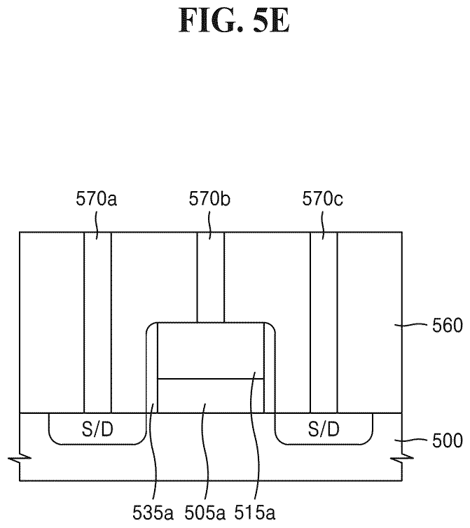

FIGS. 5A to 5E are side cross-sectional views illustrating a method of forming a semiconductor device according to an embodiment.

Referring to FIG. 5A, a gate dielectric 505 (e.g., silicon oxide) may be formed on a substrate 500. The substrate 500 may be a semiconductor substrate, such as a silicon substrate. A gate layer 515 (e.g., doped polysilicon) may be formed on the gate dielectric 505. A hardmask layer 520 may be formed on the gate layer 515.

Referring to FIG. 5B, a resist pattern 540b may be formed on the hardmask layer 520. The resist pattern 540b may be formed using a resist composition according to example embodiments. The resist pattern 540b may be formed from a resist composition including a photoacid generator, an organic solvent, and optionally a quencher and a base resin.

Referring to FIG. 5C, the gate layer 515 and the gate dielectric 505 may be etched to form a hardmask pattern 520a, a gate electrode pattern 515a, and a gate dielectric pattern 505a.

Referring to FIG. 5D, a spacer layer may be formed over the gate electrode pattern 515a and the gate dielectric pattern 505a. The spacer layer may be formed using a deposition process (e.g., CVD). The spacer layer may be etched to form spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

Referring to FIG. 5E, an interlayer insulating layer 560 (e.g., oxide) may be formed on the substrate 500 to cover the gate electrode pattern 515a, gate dielectric pattern 505a, and spacers 535a. Then, electrical contacts 570a, 570b, and 570c may be formed in the interlayer insulating layer 560 to connect to the gate electrode 515a and the S/D regions. The electrical contacts may be formed of a conductive material (e.g., metal). Although not illustrated, a barrier layer may be formed between sidewalls of the interlayer insulating layer 560 and the electrical contacts 570a, 570b, and 570c. While FIGS. 5A to 5E illustrate an example of forming a transistor, inventive concepts are not limited thereto.

A resist composition according to one or more embodiments may be used in a patterning process to form other types of semiconductor devices. The resist composition may include a photoacid generator, an organic solvent, and optionally a quencher and a base resin.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A resist composition comprising:
a polymer comprising a first repeating unit represented by Formula 1;
a photoacid generator; and
an organic solvent, 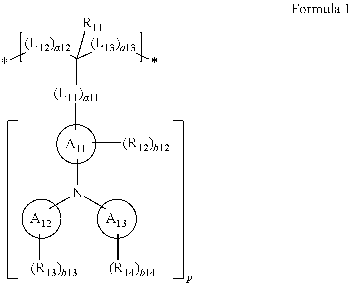
wherein, in Formula 1,
L₁₁ to L₁₃ are each independently a single bond; O; S; C(═O); C(═O)O; OC(═O); C(═O)NH; NHC(═O); or a linear, branched, or cyclic C₁-C₃₀ divalent hydrocarbon group which optionally contains a hetero atom,
a11 to a13 are each independently an integer from 1 to 4;
A₁₁ to A₁₃ are each independently a C₆-C₃₀ aryl group,
R₁₁ to R₁₄ are each independently: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which optionally contains a hetero atom,
an adjacent two of R₁₂, R₁₃ and R₁₄ are optionally bonded to each other to form a condensed ring,
b12 to b14 are each independently selected from an integer from 1 to 10,
p is an integer from 1 to 5, and
* is a binding site with an adjacent atom.

2. The resist composition of claim 1, wherein L₁₁ to L₁₃ are each independently: a single bond; O; S; C(═O); C(═O)O; OC(═O); C(═O)NH; NHC(═O); a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

3. The resist composition of claim 1, wherein A₁₁ to A₁₃ are each independently a benzene group, a naphthalene group, a phenanthrene group, an anthracene group, a pyrene group, a chrysene group, or an indene group.

4. The resist composition of claim 1, wherein R₁₁ to R₁₄ are each independently
hydrogen; deuterium; halogen; a cyano group; a hydroxy group; an amino group; a carboxylic acid group; a thiol group; or a C₁-C₂₀ alkyl group, a C₃-C₂₀ cycloalkyl group, and a C₆-C₂₀ aryl group, each unsubstituted or substituted with deuterium, halogen, a cyano group, a hydroxyl group, an amino group, a carboxylic acid group, a thiol group, an ester moiety, a sulfonic ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, or a C₆-C₂₀ aryl group, or
a combination thereof.

5. The resist composition of claim 1, wherein the first repeating unit is represented by Formula 1-1: 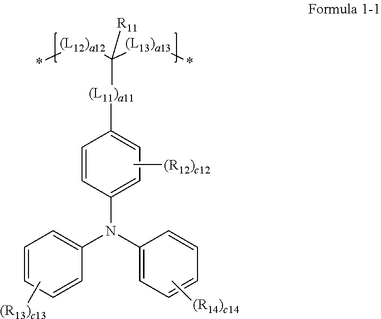
wherein, in Formula 1-1,
L₁₁ to Lis, a11 to a13, and R₁₁ to R₁₄ are the same as described in connection with Formula 1,
c12 is an integer from 1 to 4,
c13 and c14 are each an integer from 1 to 5, and
* is a binding site with an adjacent atom.

6. The resist composition of claim 1, wherein the first repeating unit is selected from Group I:

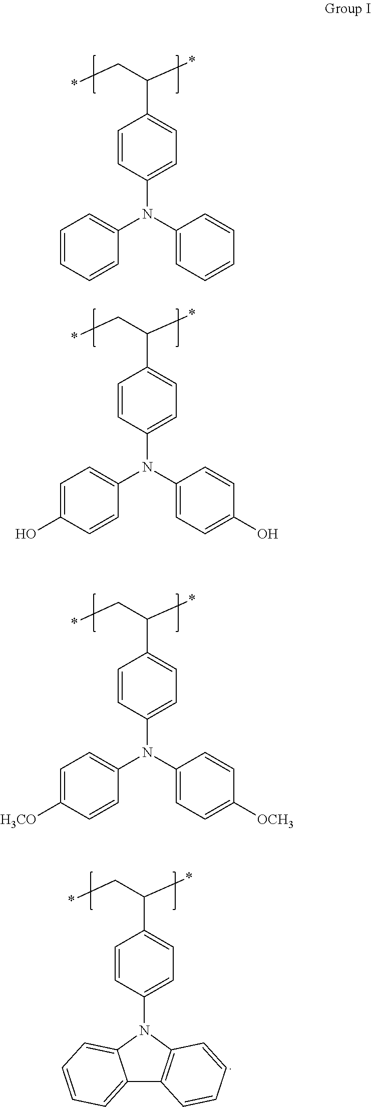

7. The resist composition of claim 1, wherein
the polymer further comprises at least one of a second repeating unit represented by Formula 2 and a third repeating unit represented by Formula 3, 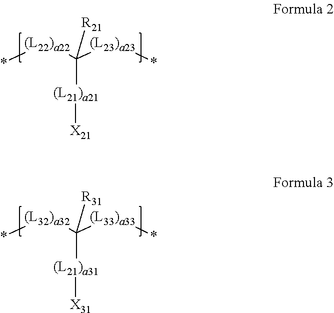
wherein, in Formulae 2 and 3,
L₂₁ to L₂₃ and L₃₁ to Las are each independently: a single bond; O; S; C(═O);
C(═O)O; OC(═O); C(═O)NH; NHC(O); or a linear, branched, or cyclic C₁-C₃₀ divalent hydrocarbon group which optionally contains a hetero atom,
a21 to a23 and a31 to a33 are each independently an integer from 1 to 4,
R₂₁ and R₃₁ are each independently: hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which optionally contains a hetero atom,
X₂₁ is an acid labile group,
X₃₁ is a non-acid labile group, and
* is a binding site with an adjacent atom.

8. The resist composition of claim 7, wherein X₂₁ is represented by Formula 5: 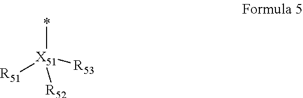
wherein, in Formula 5,
X₅₁ is a carbon atom or a silicon atom,
R₅₁ to R₅₃ are each independently hydrogen; deuterium; halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group which optionally contains a hetero atom,
each of R₅₁ to R₅₃ is not selected from hydrogen, deuterium, halogen, a cyano group, and an amino group at the same time,
an adjacent two of R₅₁ to R₅₃ are optionally bonded to each other to form a condensed ring, and
* indicates a binding site to a neighboring atom.

9. The resist composition of claim 7, wherein the second repeating unit is represented by any one of Formulae 2-1 and 2-2: 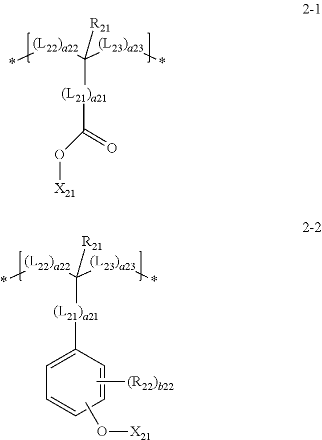
wherein, in Formulae 2-1 and 2-2,
L₂₁ to L₂₃, a21 to a23, R₂₁, and X₂₁ are the same as described in connection with Formula 2,
R₂₂ are each independently hydrogen; or a linear, branched, or cyclic C₁-C₃₀ monovalent hydrocarbon group which optionally contains a heteroatom,
b22 is an integer from 1 to 4, and
* indicates a binding site to a neighboring atom.

10. The resist composition of claim 7, wherein the second repeating unit is selected from Group II:

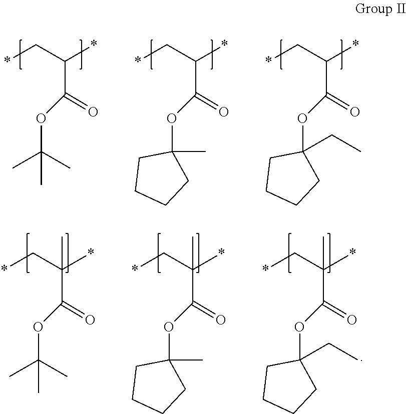

11. The resist composition of claim 7, wherein
X₃₁ is: hydrogen; halogen; a cyano group; a hydroxy group; a carboxylic acid group; a thiol group; an amino group; or a linear, branched, or cyclic C₁-C₃₀ monovalent hydrocarbon group which optionally contains one or more polar moieties selected from halogen, a cyano group, a hydroxyl group, a thiol group, a carboxylic acid group, O, C═O, C(═O)O, OC(═O), S(═O)O, OS(═O), a lactone moiety, a sultone moiety, and a carboxylic anhydride moiety.

12. The resist composition of claim 7, wherein the third repeating unit is represented by any one of Formulae 3-1 and 3-2: 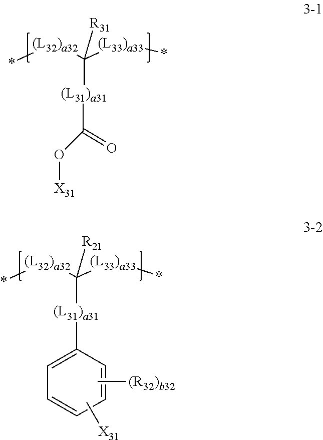
wherein, in Formulae 3-1 and 3-2,
L₃₁ to L₃₃, a31 to a33, R₃₁, and X₃₁ are the same as described in connection with Formula 3,
R₃₂ are each independently hydrogen; or a linear, branched, or cyclic C₁-C₃₀ monovalent hydrocarbon group which optionally contains a heteroatom,
b32 is an integer from 1 to 4, and
* indicates a binding site to a neighboring atom.

13. The resist composition of claim 7, wherein the third repeating unit is selected from Group III:

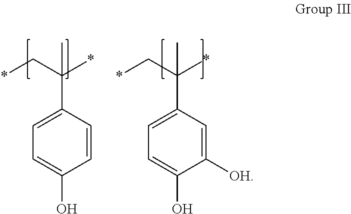

14. The resist composition of claim 1, wherein the polymer is included in an amount of about 0.1 parts by weight to about 80 parts by weight based on 100 parts by weight of the resist composition.

15. The resist composition of claim 1, wherein the photoacid generator is represented by Formula 7:
B₇₁⁺A₇₁⁻ Formula 7
wherein, in Formula 7,
B₇₁⁺ is represented by Formula 7A,
A₇₁⁻ is represented by any of Formulae 7B to 7D, and
B₇₁⁺ and A₇₁⁻ are optionally linked via a carbon-carbon covalent bond; 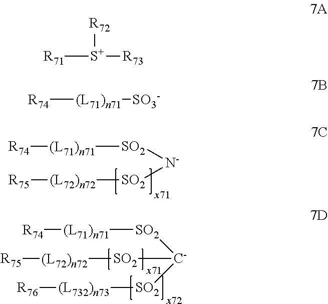
wherein, in Formulae 7A to 7D,
L₇₁ to L₇₃ are each independently a single bond or CRR′,
R and R′ are each independently hydrogen, deuterium, halogen, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 are each independently 1, 2, or 3,
x71 and x72 are each independently 0 or 1,
R₇₁ to R₇₃ are each independently a linear, branched, or cyclic C₁-C₃₀ monovalent hydrocarbon group which optionally contains a heteroatom,
an adjacent two of R₇₁ to R₇₃ are optionally bonded to each other to form a condensed ring, and
R₇₄ to R₇₆ are each independently: hydrogen; halogen; or a linear, branched, or cyclic C₁-C₃₀ monovalent hydrocarbon group which optionally contains a heteroatom.

16. The resist composition of claim 1, further comprising:
a quencher.

17. The resist composition of claim 16, wherein the quencher is represented by Formula 8:
B₈₁⁺A₈₁⁻ Formula 8
wherein, in Formula 8,
B₈₁⁺ is represented by any one of the Formulae 8A to 8C,
A₈₁⁻ is represented by any one of Formulae 8D to 8F, and
B₈₁⁺ and A₈₁⁻ are optionally linked via a carbon-carbon covalent bond, 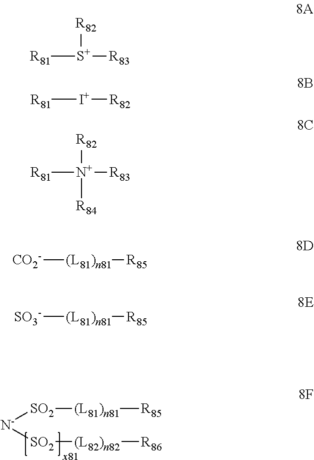
wherein, in Formulae 8A to 8F,
L₈₁ and L₈₂ are each independently a single bond or CRR′,
R and R′ are each independently hydrogen, deuterium, halogen, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 are each independently 1, 2, or 3,
x81 is 0 or 1,
R₈₁ to R₈₄ are each independently a linear, branched, or cyclic C₁-C₃₀ monovalent hydrocarbon group which optionally contains a heteroatom,
an adjacent two of R₈₁ to R₈₄ are optionally bonded to each other to form a condensed ring, and
R₈₅ and R₈₆ are each independently hydrogen, halogen, or a linear, branched, or cyclic C₁-C₃₀ monovalent hydrocarbon group which optionally contains a heteroatom.

18. A pattern forming method comprising:
forming a resist film by applying the resist composition of claim 1 on a substrate;
exposing at least a portion of the resist film to high energy rays to provide an exposed resist film; and
developing the exposed resist film using a developing solution.

19. The pattern forming method of claim 18, wherein the exposing the at least a portion of the resist film is performed by irradiating at least one of ultraviolet rays, deep ultraviolet rays (DUV), extreme ultraviolet rays (EUV), X-rays, γ-rays, electron beams (EBs), or α-rays.

20. The pattern forming method of claim 18, wherein, in the exposing the at least a portion of the resist film, the polymer is ionized to generate radical cations and electrons.
